(19) United States
(12) Patent Application Publication
(10) Pub. No.: US 2005/0042864 A1
(43) Pub. Date: Feb. 24, 2005

(54) Ohmic contact structure and method for the production of the same

(76) Inventors: Georg Bruderl, Burglengenfeld (DE); Berthold Hahn, Hemau (DE); Volker Harle, Waldetzenberg (DE); Hans-Jurgen Lugauer, Sinzing (DE); Uwe Strauss, Bad Abbach (DE); Andreas Weimar, Regensburg (DE)

Correspondence Address: COHEN, PONTANI, LIEBERMAN & PAVANE, 551 FIFTH AVENUE, SUITE 1210, NEW YORK, NY, 10176, US

(21) Appl. No.: 10/495,620

(22) PCT Filed: Nov. 12, 2002
(86) PCT No.: PCT/DE02/04178

(30) Foreign Application Priority Data
Nov. 12, 2001 (DE) 101 55 442.7

(51) Int. Cl. H01L 21/44; H01L 23/48; H01L 23/52; H01L 29/40

(52) U.S. Cl. 438/659; 438/658; 257/773; 257/734; 257/742

(57) ABSTRACT

An ohmic contact structure having a metallization (14) arranged on a semiconductor material (10), a contact layer being formed in the semiconductor material (10), which contact layer has a first partial region adjoining the metallization (14) and a second partial region (18) arranged downstream of the first partial region. The contact layer is doped in such a way that the doping concentration (N₂) in the first partial region (12) is greater than the doping concentration (N₁) in the second partial region (18).

The present invention relates to an ohmic contact structure between a metallization and a semiconductor material according to the preamble of patent claim 1 and to a method for producing such an ohmic contact structure according to the preamble of patent claim 12.

In typical applications in the field of semiconductor technology, electric current flows through semiconductor components during their operation. Electrical contact is made with the semiconductor components generally by using contacts made of metal, which are intended to have a lowest possible contact resistance between the metallization and the semiconductor material. Such metal-semiconductor contacts are usually referred to as ohmic contacts.

It is generally known that, on the one hand, a lowest possible interface barrier between the components and, on the other hand, a highest possible net concentration of the donors or acceptors in the semiconductor near the contact area are crucial for a low-resistance contact between metal and semiconductor.

The height of the interface barrier is determined, inter alia, by the work function of the metal or of the alloy formed after contact annealing and by interface states which define the Fermi level depending on the density and electronic occupation. Thin insulation layers between the semiconductor material and the metal, e.g. on account of inadequate cleaning prior to metallization, may lead to an additional influencing of the interface barrier.

It is furthermore known that, in the case of a p-conducting semiconductor material, the contact resistance between semiconductor material and metallization can be reduced by using a metal with a highest possible work function. Investigations in this respect have been disclosed for example by H. Ishikawa et al. in “Effects of Surface Treatments and Metal Work Functions on Electrical Properties at p-GaN/Metal Interfaces”, J. Appl. Phys., Vol. 81, No. 3, 1997, pages 1315-1322.

In the case of p-doped semiconductors, the minority charge carriers, i.e. the holes, predominantly contribute to the current flow in two ways. Firstly, the minority charge carriers can be raised over the interface barrier by thermal activation; secondly, they can tunnel through said interface barrier. The tunneling mechanism depends exponentially on the width of said interface barrier, which, for its part, is determined by the width of the space charge zone in the semiconductor material. This width of the space charge zone is defined by the net concentration of acceptors (i.e. the acceptor concentration minus the donor concentration) for p-doped semiconductors. The higher said net concentration, the higher the negative space charge density and the smaller the width of the space charge zone.

The importance of GaN as semiconductor material has increased in recent years. In particular, light-emitting diodes and photodetectors based on GaN which have an increasingly good efficiency have become known in the meantime. It has been found that a self-compensation effect occurs in the case of Mg-doped p-GaN, i.e. that there is an optimum Mg concentration in GaN with regard to the acceptor concentration and thus also the hole concentration. This optimum Mg concentration in GaN was determined at 2×10¹⁹ cm⁻³ for example by U. Kaufmann et al. in “Hole Conductivity and Compensation in Epitaxial GaN:Mg Layers”, Phys. Rev. B, Vol. 62, No. 16, 2000, pages 10867-10872; this value could also be confirmed by other references.

Despite the above insights, however, only a contact resistivity of the order of magnitude of approximately 10⁻² Ωcm² has been able to be obtained for p-doped GaN, which is clearly too high for many technical applications.

Therefore, it is an object of the present invention to improve an ohmic contact structure between a metallization and a semiconductor material in such a way that the contact resistivity is reduced further. A further object of the invention is to provide a method for producing such an ohmic contact structure.

These objects are achieved by means of an ohmic contact structure having the features of patent claim 1 and a method for producing an ohmic contact structure having the features of patent claim 12. Subclaims 2 to 11 and 13 to 21 relate to advantageous developments of the invention.

The ohmic contact structure according to the invention between a metallization and a semiconductor material is characterized in that the semiconductor material has a contact layer having a first partial region adjoining the metallization and a second partial region adjoining the first partial region, the doping in the first partial region being greater than that in the second partial region.

The invention is based on the insight that the electronic occupation of the defects in the vicinity of the surface of a semiconductor material does not correspond to that within the semiconductor layer. Rather, in the vicinity of the semiconductor surface, the doping concentration required for a maximum concentration of negative space charges is shifted in comparison with the doping concentration for a maximum hole concentration within the semiconductor layer. In order to obtain a contact with the lowest possible resistance between the semiconductor layer and the metallization, it is thus necessary, in the vicinity of the contact area, to choose a usually distinctly different doping concentration than is deemed to be optimal within the semiconductor layer, thereby bringing about a smaller width of the space charge zone and, consequently, a lower tunneling resistance and thus contact resistance. Below this contact layer, the semiconductor layer can then be optimized for other properties independently of the requirement for a lower contact resistivity.

Preferably, the doping concentration in the first partial region of the contact layer of the semiconductor material is chosen to be higher than that doping concentration which leads to a maximum conductivity within the semiconductor material.

The invention is advantageous, in particular, if the semiconductor material is Mg-doped GaN. In this case, the Mg concentration in the first partial region of the contact layer of the semiconductor material is preferably greater than or equal to 3×10¹⁹ cm⁻³, and particularly preferably lies between 3×10¹⁹ cm⁻³ and 5×10²⁰ cm⁻³ inclusive.

In order to further reduce the contact resistivity, it is advantageous to choose a metal or a metal compound with a highest possible work function of at least 4.0 eV for the metallization.

Such an ohmic contact structure can be employed in particular for semiconductor components such as, for example, light-emitting diodes or laser diodes.

The above and also further features and advantages of the invention are explained in more detail in the description below on the basis of a preferred exemplary embodiment with reference to the accompanying drawings, in which:

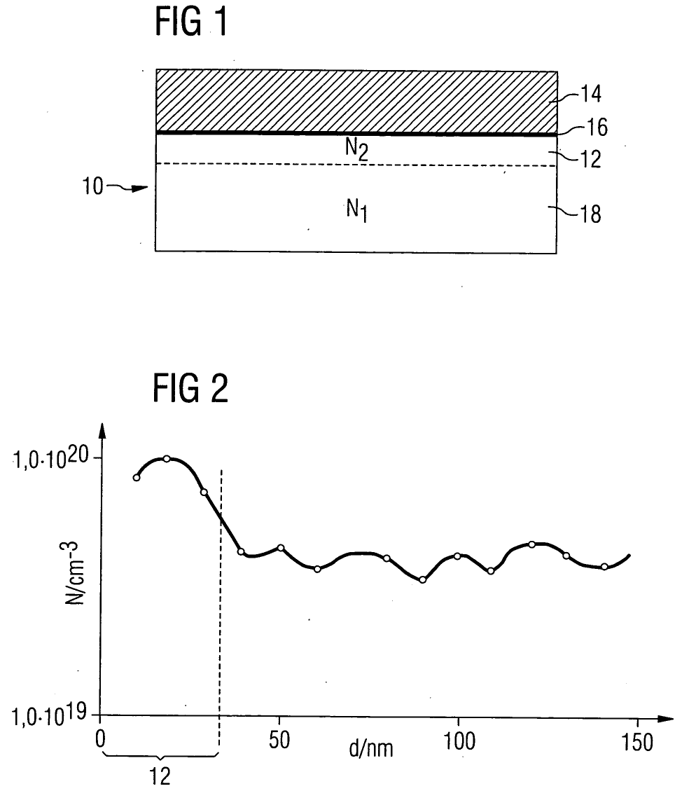

FIG. 1 shows a diagrammatic illustration of an ohmic contact structure in accordance with the present invention; and

FIG. 2 shows a diagram for illustrating the doping concentration in the semiconductor layer of the ohmic contact structure of FIG. 1.

The contact structure between a semiconductor material 10 and a metallization 14 as illustrated in FIG. 1 has a contact area 16 between the semiconductor material 10 and the metallization 14 and also a contact layer formed with a first partial region 12 and a second partial region 18.

In the preferred exemplary embodiment described here, the semiconductor material is GaN which is formed by means of an MOVPE (Metal Organic Vapor Phase Epitaxy) method and is doped with Mg. However, it shall expressly be pointed out at this juncture that the present invention is not just restricted to this choice of material, rather the insights of the present invention can also be applied to any other semiconductor materials desired. Preferably, however, the invention is applied to semiconductor materials of the general formula AlₓGa_{y}In_{z}N where 0≦x, y, z≦1 and x+y+z=1.

The Mg doping concentration N₁ within the semiconductor layer 10 is preferably 2×10¹⁹ cm⁻³. This concentration leads to a maximum concentration of free charge carriers (holes in this case) and thus to a maximum conductivity in the semiconductor layer 10. This optimum value is based on the insights already mentioned in the introduction to the description.

Since it has been found that the optimum doping concentration in the region of the semiconductor surface usually distinctly deviates from the optimum doping concentration N1 within the semiconductor layer 10, a region 12 is formed in the semiconductor layer 10 in the vicinity of the contact area 16 to be formed, which region 12 has a different doping concentration N₂, which is greater than the optimum doping concentration within the semiconductor layer.

In the case of Mg-doped GaN, the optimum doping concentration N₂ in said partial region 12 of the contact layer lies above the optimum doping concentration N₁ within the semiconductor layer 10 and is preferably more than 3×10¹⁹ cm⁻³. A minimum contact resistance of the ohmic contact structure was able to be achieved with an Mg concentration of between approximately 3×10¹⁹ cm⁻³ and 5×10²⁰ cm⁻³. FIG. 2 illustrates such an Mg concentration profile in the layer thickness direction of the semiconductor layer 10 proceeding from the contact area 16. In the case of further doping materials, similar concentration profiles are to be set in the contact layer in an analogous manner.

The table below shows results of investigations obtained in the case of a p-doped GaN semiconductor with different Mg concentrations N₂ in the partial region 12 of the contact layer adjoining the metallization. In this case, the Mg concentration N₂ in this region was determined by means of SIMS (Secondary Ion Mass Spectroscopy), the hole concentration p₂ was determined by means of HALL measurements and the contact resistivity R_{c} was determined by means of C-TLM (Circular Transmission Line Method). Moreover, the mobility μ of the holes is additionally specified in the table for the sake of completeness.

| N₂ in cm⁻³ | p₂ in cm⁻³ | μ in cm²/Vs | R_{c} in Ω cm² |
|---|---|---|---|
| 3 × 10¹⁹ | 6.36 × 10¹⁷ | 8.4 | approx. 100 × 10⁻³ |
| 6.5 × 10¹⁹ | 3.38 × 10¹⁷ | 7.8 | approx. 3 × 10⁻³ |
| 9 × 10¹⁹ | 1.15 × 10¹⁷ | 6.3 | approx. 4 × 10⁻³ |

In order to further reduce the contact resistance R_{c} between the metallization 14 and the semiconductor memory 10, it is advantageous to use a metal or a metal compound with a highest possible work function of at least 4.0 eV. This measure, already known per se, leads, in combination with the present invention, to particularly low-resistance contact structures.

Furthermore, the ohmic contact structure of the present invention can be combined with any desired methods for cleaning the semiconductor surface prior to metallization and with any desired annealing processes after the metallization operation.

1. An ohmic contact structure having a metallization (14) arranged on a semiconductor material (10), a contact layer adjoining the metallization (14) being formed in the semiconductor material (10), characterized in that
the contact layer has a first partial region (12) adjoining the metallization (14) and, as seen from the metallization (12), a second partial region (18) arranged downstream of the first partial region (12), the doping concentration (N₂) in the first partial region (12) being greater than the doping concentration (N₁) in the second partial region (18).

2. The ohmic contact structure as claimed in claim 1,
characterized in that
the doping concentration (N₂) in the first partial region (12) of the contact layer is higher than that doping concentration which leads to a maximum concentration of free charge carriers within the semiconductor material.

3. The ohmic contact structure as claimed in claim 1,
characterized in that
the semiconductor material (10) is a nitride compound semiconductor, in particular a p-doped nitride compound semiconductor.

4. The ohmic contact structure as claimed in claim 3,
characterized in that
the semiconductor material (10) contains GaN, AlGaN, InGaN or AllnGaN.

5. The ohmic contact structure as claimed in claim 3,
characterized in that
the doping material for the semiconductor material is Mg.

6. The ohmic contact structure as claimed in claim 5,
characterized in that
the Mg concentration (N₂) in the first partial region (12) of the contact layer is greater than or equal to 3×10¹⁹ cm⁻³.

7. The ohmic contact structure as claimed in claim 6,
characterized in that
the Mg concentration (N₂) in the first partial region (12) in the contact layer lies between 3×10¹⁹ cm⁻³ and 5×10²⁰ cm⁻³ inclusive.

8. The ohmic contact structure as claimed in claim 7,
characterized in that
the Mg concentration (N₂) in the first partial region (12) in the contact layer lies between 3×10¹⁹ cm⁻³ and 1×10²⁰ cm⁻³ inclusive.

9. The ohmic contact structure as claimed in claim 1,
characterized in that
the metallization (14) contains a metal, a metal compound or a metal alloy having a work function which is greater than or equal to 4.0 eV.

10. A semiconductor component having an ohmic contact structure as claimed in claim 1.

11. The semiconductor component as claimed in claim 10,
characterized in that
the semiconductor component is a luminescence diode, in particular a light-emitting diode or a laser diode.

12. A method for producing an ohmic contact structure having a metallization and a semiconductor material having the method steps of: providing a semiconductor material having a contact layer and applying a a metallization (14) to the contact layer,
characterized in that
in the contact layer, a higher doping concentration (N₂) is formed in a first partial region adjoining the metallization than in a second partial region of the contact layer, arranged downstream of the first partial region.

13. The method as claimed in claim 12,
characterized in that
the doping concentration (N₂) in the first partial region (12) of the contact layer is chosen to be higher than that doping concentration which leads to a maximum concentration of free charge carriers within the semiconductor material.

14. The method as claimed in claim 12,
characterized in that
the semiconductor material (10) is a nitride compound semiconductor, in particular a p-doped nitride compound semiconductor.

15. The method as claimed in claim 14,
characterized in that
the semiconductor material (10) is GaN, AlGaN, InGaN or AllnGaN.

16. The method as claimed in claim 12,
characterized in that
the semiconductor material is deposited on a suitable substrate by means of an MOVPE method.

17. The method as claimed in claim 12,
characterized in that
the semiconductor material (10) is doped with Mg.

18. The method as claimed in claim 17,
characterized in that
the Mg concentration (N₂) in the first partial region (12) of the contact layer is greater than 3×10¹⁹ cm⁻³ inclusive.

19. The method as claimed in claim 18,
characterized in that
the Mg concentration (N₂) in the contact layer (12) of the semiconductor material (10) lies between 3×10¹⁹ cm³ and 5×10²⁰ cm⁻³ inclusive, in particular between 3×10¹⁹ cm⁻³ and 1×10²⁰ cm⁻³ inclusive.

20. The method as claimed in claim 12,
characterized in that
a metal, a metal compound or a metal alloy having a work function of more than 4.0 eV is used for the metallization (14).
